(19) United States
(12) Patent Application Publication
(10) Pub. No.: US 2005/0142857 A1
(43) Pub. Date: Jun. 30, 2005

(54) Method for forming metal line in semiconductor device

(76) Inventor: Se Young Lee, Cheongju-Shi (KR)

Correspondence Address: JACOBSON HOLMAN PLLC, 400 SEVENTH STREET N.W., SUITE 600, WASHINGTON, DC, 20004, US

(21) Appl. No.: 10/876,725

(22) Filed: Jun. 28, 2004

(30) Foreign Application Priority Data
Dec. 30, 2003 (KR) 2003-100163

(51) Int. Cl. H01L 21/20; H01L 21/4763; H01L 21/461

(52) U.S. Cl. 438/638; 438/674; 438/692

(57) ABSTRACT

The present invention discloses a method for forming a metal line in a semiconductor device which can prevent metal plating from being protruded from a specific portion, prevent bridges from being generated between metal lines by a uniform thickness, and improve reliability of the process, by forming a dual damascene pattern including a trench and a via hole on an insulation film, forming a metal seed layer on the sidewalls and bottom surface of the dual damascene pattern except for the sidewalls of the trench, and forming the metal line by filling a metal material in the dual damascene pattern by an electroplating method.

### BACKGROUND

1. Field of the Invention

The present invention relates to a method for forming a metal line in a semiconductor device, and more particularly to, a method for forming a metal line in a semiconductor device according to an electroplating method.

2. Discussion of Related Art

An essential device for implementing an Si CMOS technology in an RF IC is an inductor. However, a standard logic process does not obtain a sufficient quality factor Q for the RF IC. In order to obtain a high Q value, parasitic resistance elements generated in a metal line must be reduced, and loss of an eddy current and a displacement current flowing through an Si substrate must be reduced. For this, not aluminum but copper is used as a metal for forming the inductor, or a thickness of the metal is set larger than in a standard process to reduce a resistance, and a distance (height) from the lower layer is obtained as long as possible.

In order to solve the above problems, a conventional method controls a thickness of a metal line for forming an inductor, by controlling a development depth of a positive photoresist film by a light irradiation time to the photoresist film. Here, a general chemical mechanical polishing process does not remove a few μm of copper. Therefore, a barrier film and 1000 Å to 2000 Å of copper seed layer are formed on the photoresist film, the copper seed layer is left merely in a trench of the photoresist film according to the chemical mechanical polishing process, and copper is formed merely in the trench according to an electroplating method.

FIG. 1 is a cross-sectional diagram illustrating a conventional method for forming a metal barrier layer in a semiconductor device.

Referring to FIG. 1, a metal barrier layer 102 and an interlayer insulation film 103 are sequentially formed on a semiconductor substrate 101 on which a few elements (not shown) for forming the semiconductor device have been formed. A dual damascene pattern 104 including a trench 104a and a via hole 104b is formed on the interlayer insulation film 103. Here, the interlayer insulation film 103 is formed by using a photoresist, and an exposure depth and width of the dual damascene pattern 104 are controlled. On the other hand, a metal seed layer 105 is formed on the inner walls of the dual damascene pattern 104. A metal material is filled in the dual damascene pattern 104 according to the electroplating method, to form a metal line 106. Preferably, the metal seed layer 105 and the metal line 106 are formed by using copper.

As described above, when the metal seed layer 105 is formed on the inner walls of the dual damascene pattern 104 and the metal is plated thereon according to the electroplating method, the metal is also plated in the vertical direction on the edges 105a of the metal seed layer 105 formed in the vertical direction to the sidewalls of the trench 104a. The metal is plated on the edges 105a of the metal seed layer 105, starting from the surface height of the interlayer insulation film 103. Accordingly, the metal line 106 is formed higher than the surface of the interlayer insulation film 103.

When the metal line 106 is partially protruded, short may be occurred between the metal lines. In addition, the protruded portions are not easily removed according to the chemical mechanical polishing process.

### SUMMARY OF THE INVENTION

The present invention is directed to a method for forming a metal line in a semiconductor device which can prevent metal plating from being protruded from a specific portion, prevent bridges from being generated between metal lines by a uniform thickness, and improve reliability of the process, by forming a dual damascene pattern including a trench and a via hole on an insulation film, forming a metal seed layer on the sidewalls and bottom surface of the dual damascene pattern except for the sidewalls of the trench, and forming the metal line by filling a metal material in the dual damascene pattern according to an electroplating method.

One aspect of the present invention is to provide a method for forming a metal line in a semiconductor device, comprising the steps of: forming a photoresist film on a semiconductor substrate; changing a photoresist film in a presumed trench formation region into a trapezoid to a predetermined depth by a primary exposure process using a trench mask; changing the photoresist film in a presumed via hole formation region by a secondary exposure process using a via hole mask; removing the photoresist film changed by the exposure processes; forming a metal seed layer by a physical vapor deposition method, except for the side walls of the trench; removing the metal seed layer on the photoresist film; and forming a metal line in a dual damascene pattern by an electroplating method.

Preferably, the metal line is formed by using copper.

The primary exposure process changes the photoresist film into the trapezoid to a predetermined depth, by defocusing light transmitted from a lens on the photoresist film.

The metal seed layer on the photoresist film is removed according to a chemical mechanical polishing process. A slurry containing 0 wt % to 5 wt % of abrasive is provided in the chemical mechanical polishing process. The slurry contains DL_malic acid, methanol, benzotriazole or malic acid.

On the other hand, an abrasion ratio of the chemical mechanical polishing process is controlled by an oxidizer or a corrosion inhibitor.

The chemical mechanical polishing process controlling the abrasion ratio by using the corrosion inhibitor includes the steps of: supplying the corrosion inhibitor to a pad for 10 seconds to 3 minutes to contact the surface of the metal seed layer; stopping supply of the slurry, and supplying the corrosion inhibitor for 10 seconds to 3 minutes during the chemical mechanical polishing process; and supplying the corrosion inhibitor for 10 seconds to 3 minutes after finishing the chemical mechanical polishing process. Here, the corrosion inhibitor is benzotriazole (BTA), and a concentration of the corrosion inhibitor is set between 0.01 wt % and 1 wt %.

A mixing ratio of the oxidizer mixed with the slurry ranges from 1 wt % to 50 wt % in the chemical mechanical polishing process controlling the abrasion ratio by using the oxidizer. Here, the oxidizer is selected from H₂O₂, Fe(NO₃)₃, KIO₂ and H₅IO₆.

The method for forming the metal line in the semiconductor device further includes the steps of: removing the photoresist film; and forming an insulation film over the resulting structure including the metal line, after forming the metal line.

### BRIEF DESCRIPTION OF THE DRAWINGS

FIG. 1 is a cross-sectional diagram illustrating a conventional method for forming a metal line in a semiconductor device; and

FIGS. 2A to 2I are cross-sectional diagrams illustrating sequential steps of a method for forming a metal line in a semiconductor device in accordance with a preferred embodiment of the present invention.

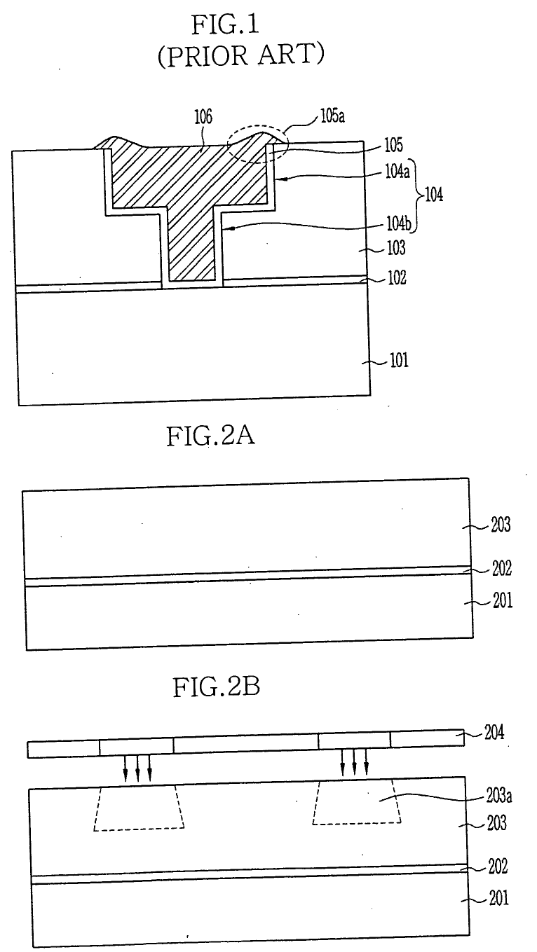

### DETAILED DESCRIPTION OF PREFERRED EMBODIMENTS

A method for forming a metal line in a semiconductor device in accordance with a preferred embodiment of the present invention will now be described in detail with reference to the accompanying drawings.

In the case that it is described that one film is disposed ‘on’ another film or a semiconductor substrate, one film can directly contact another film or the semiconductor substrate, or the third film can be positioned between them. In the drawings, a thickness or size of each layer is exaggerated to provide clear and accurate explanations. Wherever possible, the same reference numerals will be used throughout the drawings and the description to refer to the same or like parts.

In accordance with the present invention, in a state where a metal seed layer is not formed on the sidewalls of a trench but formed on the bottom surface of the trench and the sidewalls and bottom surface of a via hole, a metal line is formed according to an electroplating method. Here, various methods can be used to form the metal seed layer merely on the bottom surface of the trench and the sidewalls and bottom surface of the via hole. One of the examples will now be explained.

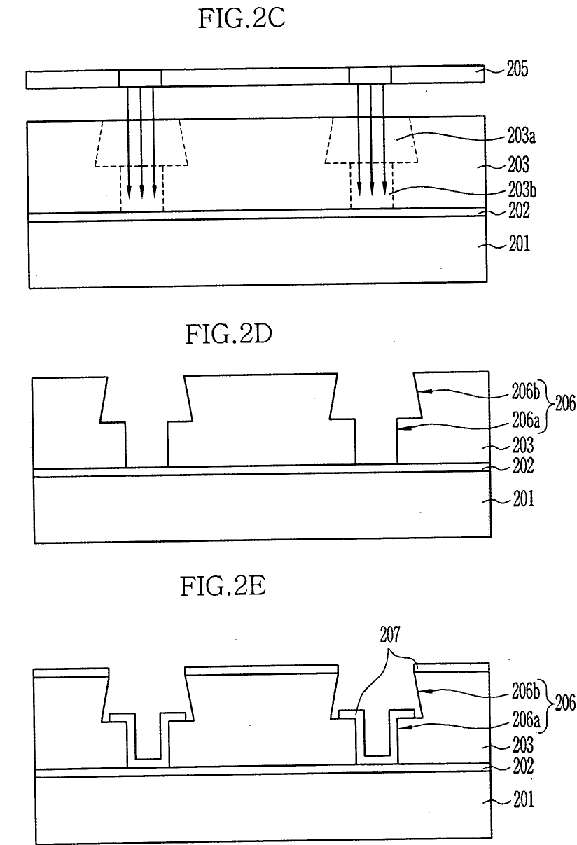

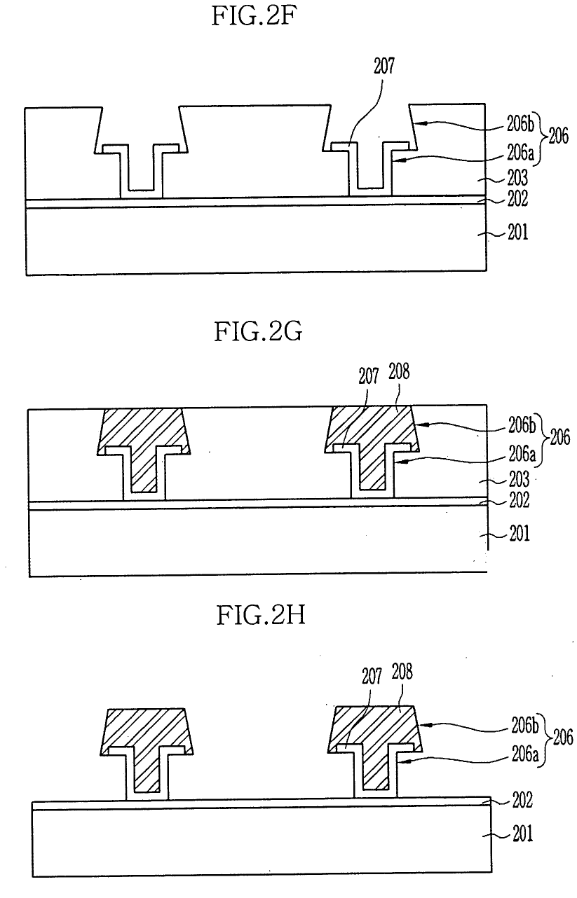

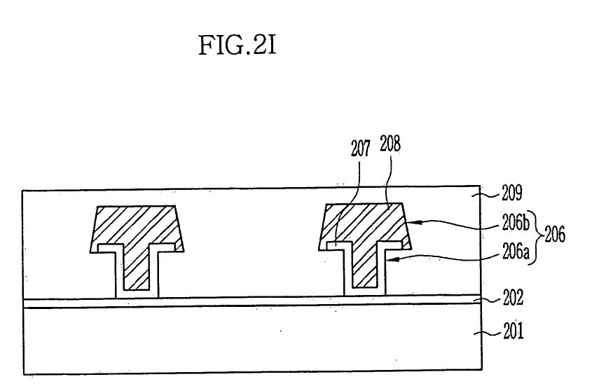

FIGS. 2A to 2I are cross-sectional diagrams illustrating sequential steps of the method for forming the metal line in the semiconductor device in accordance with the preferred embodiment of the present invention.

As illustrated in FIG. 2A, a metal barrier layer 202 is formed on a semiconductor substrate 201 on which a few elements (not shown) for forming the semiconductor device such as a transistor have been formed, and a photoresist film 203 is formed thereon.

As shown in FIG. 2B, a primary exposure process is performed by using a trench mask 204 on which a presumed trench formation region is defined. In order to form the trench on the photoresist film 203, the primary exposure process controls an exposure time and intensity, so that the photoresist film 203 can be changed to a target depth for forming the trench. Accordingly, the photoresist film 203a is defined in the presumed trench formation region according to the primary exposure process.

Here, the primary exposure process is performed to defocus a light transmitted from a lens on the photoresist film 203, thereby defining the presumed trench formation region as a trapezoid having a top smaller than a bottom. That is, the presumed trench formation region is defined according to the primary exposure process, so that the sidewalls of the trench cannot be vertical but have an angle of 80 to 89.9°.

As depicted in FIG. 2C, a secondary exposure process is performed by using a via hole mask 205 on which a presumed via hole region has been defined. Therefore, the photoresist film 203b is defined in the presumed via hole region according to the secondary exposure process. Here, the presumed via hole formation region is included in the presumed trench formation region.

The primary and secondary exposure processes of FIGS. 2B and 2C can be performed in a reverse order. That is, the secondary exposure process can be performed before the primary exposure process.

As shown in FIG. 2D, the changed portions of the photoresist film 203 are removed according to the primary and secondary exposure processes. As a result, a dual damascene pattern 206 including a trench 206a and a via hole 206b is formed on the photoresist film 203.

As illustrated in FIG. 2E, a metal seed layer 207 is formed over the resulting structure including the dual damascene pattern 206. Preferably, the metal seed layer 207 is formed by using Cu. Here, the metal seed layer 207 is formed according to a physical vapor deposition method, except for the sidewalls of the trench 206a. The physical vapor deposition method has straight line properties. When the metal seed layer 207 is formed according to the physical vapor deposition method, the sidewalls of the trench 206a are covered by the top edges of the photoresist film 203. Therefore, the metal is not deposited on the sidewalls of the trapezoid trench 206a. That is, the metal seed layer 207 is formed on the top surface of the photoresist film 203, the bottom surface of the trench 206a, and the sidewalls and bottom surface of the via hole 206b. Because a top width of the trench 206a is smaller than a bottom width thereof, the metal seed layer 207 is formed on the bottom surface of the trench 206a corresponding to the top width, but not formed on the bottom surfaces of the edges of the trench 206a.

Referring to FIG. 2F, the metal seed layer 207 formed on the photoresist film 203 is removed. The metal seed layer 207 on the photoresist film 203 can be removed according to a chemical mechanical polishing process. In this case, the metal seed layer 207 is removed by using an abrasive free slurry or a slurry containing an abrasive below 5 wt %. The slurry contains DL_malic acid, methanol, benzotriazole or malic acid.

On the other hand, an abrasion ratio of the metal seed layer 207 will now be explained.

For example, when the metal seed layer 207 is formed by using copper, the abrasion ratio of the metal seed layer 207 can be controlled by using a copper oxidizer (for example, H₂O₂) or a copper corrosion inhibitor (for example, benzotriazole; BTA), which will now be described in more detail.

When the abrasion ratio is controlled by the corrosion inhibitor, BTA having a concentration of 0.01 wt % to 1 wt % is supplied to a pad for 10 seconds to 3 minutes as the corrosion inhibitor prior to the chemical mechanical polishing process, to contact the surface of the metal seed layer 207. In order to protect the metal seed layer 207 in the dual damascene pattern 206, supply of the slurry is stopped, and the corrosion inhibitor is supplied during the chemical mechanical polishing process. Here, the corrosion inhibitor is supplied at a pressure below 5 psi and a platen rotational speed below 600 rpm. BTA having a concentration of 0.01 wt % to 1 wt % can be supplied for 10 seconds to 3 minutes as the corrosion inhibitor. The slurry is re-supplied, and the chemical mechanical polishing process is performed. When the chemical mechanical polishing process has been finished, BTA having a concentration of 0.01 wt % to 1 wt % is supplied for 10 seconds to 3 minutes as the corrosion inhibitor.

When the abrasion ratio is controlled by the oxidizer, a mixing ratio of the oxidizer mixed with the slurry is controlled between 1 wt % and 50 wt %. Preferably, the mixing ratio of the oxidizer is controlled between 20 wt % and 40 wt %. Here, H₂O₂ can be used as the oxidizer. In a state where the slurry and the oxidizer are mixed, the chemical mechanical polishing process is performed. When the metal seed layer 207 is removed in a region (not shown) where the dual damascene pattern 206 has not been formed enough to expose the metal barrier layer 202, the chemical mechanical polishing process is finished. In the case that the chemical mechanical polishing process is finished at the exposure time point of the metal barrier layer 202, the mixing ratio of the slurry to the oxidizer is controlled, so that the abrasion ratio of the metal barrier layer 202 to the metal (for example, copper) can be 1:1 to 1:5000.

In addition, the oxidizer and the corrosion inhibitor can be used to control the abrasion ratio of the metal barrier layer to the metal. Here, BTA can be used as the corrosion inhibitor, and H₂O₂, Fe(NO₃)₃, KIO₂ and H₅IO₆ can be used as the oxidizer.

Accordingly, the metal seed layer 207 is left on the sidewalls and bottom surface of the via hole 206b and on part of the bottom surface of the trench 206a.

As shown in FIG. 2G, a metal material is filled in the dual damascene pattern 206 according to an electroplating method, to form a metal line 208. Preferably, the metal line 208 is formed by using copper. In the electroplating process, the metal is not grown from the sidewalls of the trench 106a but uniformly grown from the bottom surface of the trench 106a in the vertical direction. Therefore, metal plating is not protruded from a specific portion. Moreover, the metal line 108 has a uniform thickness.

A process for removing the metal plated on the photoresist film 203 can be additionally performed after the electroplating process.

As depicted in FIG. 2H, the photoresist film (203 of FIG. 2G) is removed.

Referring to FIG. 21, an insulation film 209 is formed over the resulting structure including the metal line 208, for electrically isolating the metal line 208.

As discussed earlier, in accordance with the present invention, the method for forming the metal line in the semiconductor device can prevent metal plating from being protruded from a specific portion, prevent bridges from being generated between the metal lines by the uniform thickness, and improve reliability of the process, by forming the dual damascene pattern including the trench and the via hole on the insulation film, forming the metal seed layer on the sidewalls and bottom surface of the dual damascene pattern except for the sidewalls of the trench, and forming the metal line by filling the metal material in the dual damascene pattern according to the electroplating method.

Although the present invention has been described in connection with the embodiment of the present invention illustrated in the accompanying drawings, it is not limited thereto. It will be apparent to those skilled in the art that various substitutions, modifications and changes may be made thereto without departing from the scope and spirit of the invention.

1. A method for forming a metal line in a semiconductor device, comprising the steps of:
forming a photoresist film on a semiconductor substrate;
changing a photoresist film in a presumed trench formation region into a trapezoid to a predetermined depth by a primary exposure process using a trench mask;
changing the photoresist film in a presumed via hole formation region by a secondary exposure process using a via hole mask;
removing the photoresist film changed by the exposure processes;
forming a metal seed layer by a physical vapor deposition method, except for the side walls of the trench;
removing the metal seed layer on the photoresist film; and
forming a metal line in a dual damascene pattern by an electroplating method.

2. The method of claim 1, wherein the metal line is formed by using copper.

3. The method of claim 2, wherein the primary exposure process changes the photoresist film into the trapezoid to a predetermined depth, by defocusing light transmitted from a lens on the photoresist film.

4. The method of claim 2, wherein the metal seed layer on the photoresist film is removed by a chemical mechanical polishing process.

5. The method of claim 4, wherein a slurry containing 0 to 5 wt % of abrasive is provided in the chemical mechanical polishing process.

6. The method of claim 5, wherein the slurry comprises DL_malic acid, methanol, benzotriazole or malic acid.

7. The method of claim 4, wherein an abrasion ratio of the chemical mechanical polishing process is controlled by an oxidizer or a corrosion inhibitor.

8. The method of claim 7, wherein the chemical mechanical polishing process controlling the abrasion ratio by using the corrosion inhibitor comprises the steps of:
supplying the corrosion inhibitor to a pad for 10 seconds to 3 minutes to contact the surface of the metal seed layer;
stopping supply of the slurry, and supplying the corrosion inhibitor for 10 seconds to 3 minutes during the chemical mechanical polishing process; and
supplying the corrosion inhibitor for 10 seconds to 3 minutes after finishing the chemical mechanical polishing process.

9. The method of claim 8, wherein the corrosion inhibitor is benzotriazole.

10. The method of claim 9, wherein a concentration of the corrosion inhibitor ranges from 0.01 to 1 wt %.

11. The method of claim 7, wherein a mixing ratio of the oxidizer mixed with the slurry ranges from 1 to 50 wt % in the chemical mechanical polishing process controlling the abrasion ratio by using the oxidizer.

12. The method of either claim 7, wherein the oxidizer is selected from H₂O₂, Fe(NO₃)₃, KIO₂ and H₅IO₆.

13. The method of claim 1, further comprising the steps of:
removing the photoresist film; and
forming an insulation film over the resulting structure including the metal line, after forming the metal line.
